(19) United States
(12) Patent Application Publication
(10) Pub. No.: US 2025/0171248 A1
(43) Pub. Date: May 29, 2025

(54) TRANSFER ROBOT FOR SUBSTRATE PROCESSING APPARATUS

(71) Applicant: KABUSHIKI KAISHA YASKAWA DENKI, Fukuoka (JP)

(72) Inventors: Kensuke ONI, Fukuoka (JP); Norihisa IWASAKI, Fukuoka (JP); Yasuhiro MARUYAMA, Fukuoka (JP); Yuki YASUDA, Fukuoka (JP)

(21) Appl. No.: 18/945,116

(22) Filed: Nov. 12, 2024

(30) Foreign Application Priority Data
Nov. 24, 2023 (JP) 2023-199305

(51) Int. Cl. B65G 47/90

(52) U.S. Cl. CPC B65G 47/90

(57) ABSTRACT

The robot includes a hand that supports a substrate, a base, a multi-joint arm that connects the hand to the base, one or more motors that drives the multi-joint arm and changes a position of the hand relative to the base, a drive circuit that supplies driving power to the one or more motors, and a circuit case that accommodates the drive circuit and is attached to the base in a removable manner.

### CROSS-REFERENCE TO RELATED APPLICATIONS

This application is based on and claims priority from Japanese Patent Application No. 2023-199305 filed on Nov. 24, 2023 with the Japan Patent Office, the disclosure of which is incorporated herein in its entirety by reference.

### TECHNICAL FIELD

The present disclosure relates to a transfer robot for substrate processing apparatuses.

### BACKGROUND

Japanese Patent Laid-Open Publication No. 2007-038360 discloses a transfer robot including a case, a first arm attached to the case, a second arm attached to the first arm, a third arm attached to the second arm, and a fourth arm attached to the third arm. The case is provided with a built-in control device that outputs drive power supply and control signals to a motor that drives the transfer robot.

### SUMMARY

The present disclosure provides a robot that effectively achieves both space-saving and maintainability.

According to an aspect of the present disclosure, a robot includes a hand configured to support a substrate, a base, a multi-joint arm configured to connect the hand to the base, one or more motors configured to drive the multi-joint arm and change a position of the hand relative to the base, a drive circuit configured to supply driving power to the one or more motors, and a circuit case configured to accommodate the drive circuit and attached to the base in a removable manner.

According to the present disclosure, it is possible to provide a robot that is effective in achieving both space-saving and maintainability.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a configuration of a robot.

FIG. 2 is a front view of a base and circuit case with a cover removed.

FIG. 3 is a rear view of the base and circuit case with the cover removed.

FIG. 4 is a side view of the base and circuit case with the cover attached.

FIG. 5 is a side view illustrating an attachment portion of a second frame to a first frame.

FIG. 6 is a rear view of the base, circuit case, and power supply case.

FIG. 7 is a front view of the base, circuit case, and power supply case.

FIG. 8 is a front view illustrating the power supply case with the cover attached.

### DETAILED DESCRIPTION

In the following detailed description, reference is made to the accompanying drawing, which forms a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments will be described in detail with reference to the drawings. In the description, the same reference numerals will be given to the same elements or elements having the same functions, and redundant descriptions thereof will be omitted.

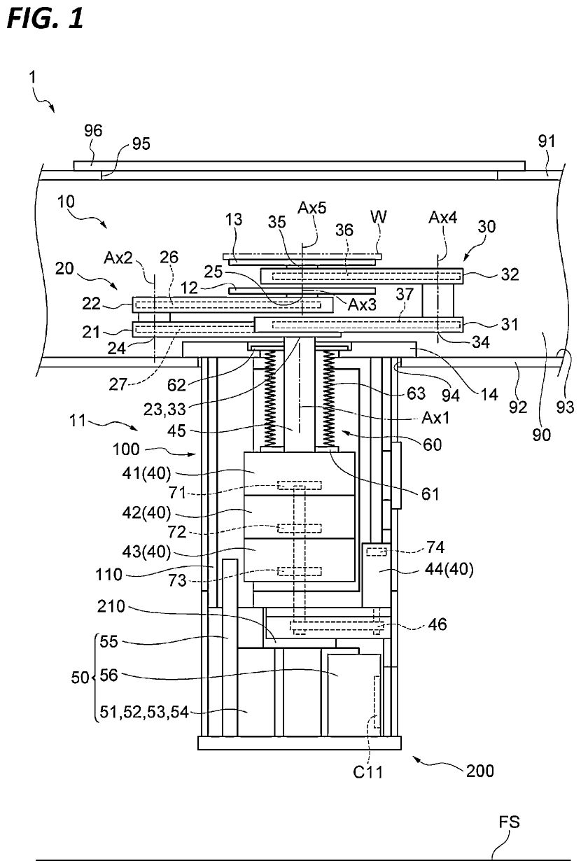

The substrate transfer device 1 illustrated in FIG. 1 is a device that transfers a substrate W in a substrate processing apparatus that performs a processing on the substrate W. Examples of the substrate W include a semiconductor substrate, a glass substrate, a mask substrate, or a Flat Panel Display (FPD) substrate. As illustrated in FIG. 1, the substrate transfer device 1 includes a chamber 90 and a robot 10. The chamber 90 accommodates the substrate W that is being transferred. For example, the chamber 90 has a horizontally extending upper plate 91 and a horizontally extending bottom plate 92 located below the upper plate 91, and accommodates the substrate W in an internal space 93 formed between the upper plate 91 and the bottom plate 92. The chamber 90 may be of a sealed type, or may be of a pressure-resistant type capable of generating a vacuum in the internal space 93.

The robot 10 transfers the substrate W in the internal space 93. For example, the robot 10 transfers the substrate W between a plurality of stations arranged around the chamber 90. The plurality of stations may include a load-lock chamber for temporarily accommodating the substrate W to be transferred and a processing chamber for processing the substrate W. For example, the robot 10 transfers the substrate W along the horizontal direction in the internal space 93.

According to an embodiment, the robot 10 includes a base 11, a hand 12, a multi-joint arm 20, one or more motors 40, and a drive circuit 50. The hand 12 supports the substrate W from below along a horizontal plane. The aforesaid “along a horizontal plane” is used to allow slight tilting with respect to the horizontal plane within a margin of error. The hand 12 may be configured to hold the substrate W by suction or other methods. The base 11 is fixed to the chamber 90.

The multi-joint arm 20 connects the hand 12 to the base 11. For example, the multi-joint arm 20 is a horizontal multi-joint arm provided between the base 11 and the hand 12, and includes an arm 21 and an arm 22, which are consecutive in order from the base 11 to the hand 12. The arm 21 is attached onto the base 11 so as to be able to pivot around an axis Ax1 along the vertical direction, and extends away from the axis Ax1. The aforesaid “along the vertical direction” is used to allow slight tilting with respect to the direction perpendicular to a horizontal plane within a margin of error.

The arm 22 is attached onto an end of the arm 21 so as to be able to pivot around an axis Ax2 along the vertical direction, and extends away from the axis Ax2. The hand 12 is attached onto an end of the arm 22 so as to be able to pivot around an axis Ax3 along the vertical direction, and extends away from the axis Ax3. In this way, the multi-joint arm 20 includes a joint 23 around the axis Ax1, a joint 24 around the axis Ax2, and a joint 25 around the axis Ax3.

In order to handle a plurality of substrates W simultaneously, the robot 10 may include a plurality of hands and a plurality of multi-joint arms respectively corresponding to the plurality of hands. For example, the robot 10 includes a hand 13 and a multi-joint arm 30, in addition to the hand 12 and the multi-joint arm 20. Similar to the hand 12, the hand 13 supports the substrate W from below along a horizontal plane. The hand 13 may be configured to support the substrate W by suction or other methods.

The multi-joint arm 30 connects the hand 13 to the base 11. For example, the multi-joint arm 30, similar to the multi-joint arm 20, includes an arm 31 and an arm 32. The arm 31 is attached onto the base 11 so as to be able to pivot around the axis Ax1, and extends away from the axis Ax1. The arm 32 is attached onto an end of the arm 31 so as to be able to pivot around an axis Ax4 along the vertical direction, and extends away from the axis Ax4. The hand 13 is attached onto an end of the arm 32 so as to be able to pivot around an axis Ax5 along the vertical direction, and extends away from the axis Ax5. In this way, the multi-joint arm 30 includes a joint 33 around the axis Ax1, a joint 34 around the axis Ax4, and a joint 35 around the axis Ax5.

The multi-joint arms 20 and 30 may be configured such that at least one set of the joints 23, 24 and 25 and the joints 33, 34 and 35 are interlocked (e.g., inter-operable) with each other. For example, the arm 21 and the arm 31 may be fixed to each other, while extending in different directions. This allows the joint 23 and the joint 33 to be interlocked, causing the arm 21 and the arm 31 to rotate integrally around the axis Ax1.

The multi-joint arm 20 may be configured such that the joint 24 and the joint 25 are inter-locked. For example, the multi-joint arm 20 may further include a transmission mechanism 26 (e.g., a pulley and a belt) that interlocks the joint 24 and the joint 25, so that the rotation of the arm 22 relative to the arm 21 and the rotation of the hand 12 relative to the arm 22, are interlocked in opposite directions. With the transmission mechanism 26, the arm 22 is rotated relative to the arm 21, allowing the hand 12 to be displaced while maintaining a constant posture of the hand 12 with respect to the arm 21.

Similarly, the multi-joint arm 30 may be configured such that the joint 34 and the joint 35 are interlocked. For example, the multi-joint arm 30 may further have a transmission mechanism 36 (e.g., a pulley and a belt) that interlocks the joint 34 and the joint 35 so that the rotation of the arm 32 relative to the arm 31 and the rotation of the hand 13 relative to the arm 32 are interlocked in opposite directions.

As described above, according to the configuration in which the joint 23 and the joint 33 are interlocked, the joint 24 and the joint 25 are interlocked, and the joint 34 and the joint 35 are interlocked, it is possible to move the hands 12 and 13 back and forth in any direction around the axis Ax1 using three motors. The robot 10 may be configured, not only to transfer the substrate W along the horizontal direction, but also to move the substrate W up and down.

The one or more motors 40 drive the multi-joint arm 20 to change the position of the hand 12 relative to the base 11. The one or more motors 40 may also drive the multi-joint arm 30 to change the position of the hand 13 relative to the base 11. Furthermore, the one or more motors 40 may move the multi-joint arm 20 and the multi-joint arm 30 up and down.

The one or more motors 40 may be built into the base 11. For example, the base 11 includes a base case 100, and the one or more motors 40 are accommodated within the base case 100.

For example, the one or more motors 40 include a motor 41, a motor 42, a motor 43, and a motor 44. The motors 41, 42, 43 and 44 are accommodated in the base case 100.

The motor 41 is, for example, an electric servo motor and has an output shaft 45 along the axis Ax1. The output shaft 45 protrudes upward from the inside of the base case 100 and is connected to the arm 21 and the arm 31. The motor 41 rotates the output shaft 45 around the axis Ax1, thereby rotating the arm 21 and the arm 31 around the axis Ax1.

The motor 42 is, for example, an electric servo motor, and drives the joint 24 via a transmission mechanism 27 (e.g., a pulley and a belt) passing through the output shaft 45 and the arm 21. For example, the motor 42 rotates the arm 22 relative to the arm 21 around the axis Ax2.

The motor 43 is, for example, an electric servo motor, and drives the joint 34 via a transmission mechanism 37 (e.g., a pulley and a belt) passing through the output shaft 45 and the arm 31. For example, the motor 43 rotates the arm 32 relative to the arm 31 around the axis Ax3. The motors 41, 42 and 43 are arranged in order from top to bottom and are fixed to each other. The motor 44 is, for example, an electric servo motor, and moves the motor 43 up and down via a transmission mechanism 46 (e.g., a pulley, a belt, and a ball screw). Consequently, the multi-joint arm 20 and the multi-joint arm 30 connected to the output shaft 45 are moved up and down.

The motors 41, 42, 43 and 44 include rotation angle sensors 71, 72, 73 and 74, respectively. The rotation angle sensor 71 detects the rotation angle of the motor 41 (e.g., the rotation angle of the output shaft 45), the rotation angle sensor 72 detects the rotation angle of the motor 42, the rotation angle sensor 73 detects the rotation angle of the motor 43, and the rotation angle sensor 74 detects the rotation angle of the motor 44. The rotation angle sensors 71, 72, 73 and 74 are rotary encoders such as optical or magnetic encoders.

To transfer the substrate W in the internal space 93, at least the hands 12 and 13 and the multi-joint arms 20 and 30 are accommodated in the internal space 93. The base 11 may be positioned outside the chamber 90. In this case, the chamber 90 may further have a chamber opening 94 to position the base 11 outside the chamber 90.

According to an embodiment, the chamber opening 94 is formed in the bottom plate 92 and opens downward. The base 11 protrudes downward from the bottom plate 92 through the chamber opening 94. In this case, the robot 10 may further include a flange 14. The flange 14 extends horizontally over the entire circumference around the axis Ax1 to partition between the multi-joint arms 20 and 30 and the base 11. The flange 14 is attached to the bottom plate 92 to close the chamber opening 94.

The flange 14 may be attached to the bottom plate 92 from below, or may be attached to the bottom plate 92 from above. When the flange 14 is attached to the bottom plate 92 from above, the upper plate 91 is formed with a loading opening 95 for loading the robot 10. The robot 10 is loaded into the internal space 93 from above through the loading opening 95, and the base 11 is passed through the chamber opening 94 from above. The chamber 90 may further include a cover 96 to close the loading opening 95.

The robot 10 may further include a sealing member 60. The sealing member 60 is provided on the flange 14 to airtightly separate the internal space of the base 11 from the external space of the base 11. For example, the sealing member 60 includes an inner seal 61, an outer seal 62, and an elastic piece 63. The inner seal 61 surrounds the output shaft 45 and is fixed to the motor 41. The inner seal 61 is, for example, a mechanical seal, and is in close contact with the output shaft 45 over the entire circumference while allowing the rotation of the output shaft 45. The outer seal 62 surrounds the output shaft 45, and is in close contact with the flange 14 over the entire circumference while being fixed to the flange 14. The elastic piece 63 is a bellows-like hose that surrounds the output shaft 45 between the inner seal 61 and the outer seal 62, and expands or contracts as the motor 41 is moved up or down by the motor 44.

The drive circuit 50 supplies driving power to the one or more motors 40. Supplying driving power includes converting power supplied from a power supply into driving power and supplying it to the one or more motors 40. Driving power refers to, for example, power that generates a magnetic field for driving movable components such as a rotor.

According to an embodiment, the drive circuit 50 includes a servo circuit 51, a servo circuit 52, a servo circuit 53, a servo circuit 54, a calculation circuit 55, and a communication circuit 56. The servo circuit 51 converts the power supplied from the power supply into driving power in response to a control command and supplies it to the motor 41. The servo circuit 52 converts the power supplied from the power supply into driving power in response to a control command and supplies it to the motor 42. The servo circuit 53 converts the power supplied from the power supply into driving power in response to a control command and supplies it to the motor 43. The servo circuit 54 converts the power supplied from the power supply into driving power in response to a control command and supplies it to the motor 44. The calculation circuit 55 calculates the control commands for the motors 41, 42, 43 and 44 to cause the multi-joint arm 20 and the multi-joint arm 30 to perform predetermined operations, and outputs the calculation results to the servo circuits 51, 52, 53 and 54, respectively. The communication circuit 56 communicates with external devices of the robot 10 in response to requests from the calculation circuit 55. Examples of external devices include a higher-level controller, a calibration device for the position of the substrate W, and others. The communication circuit 56 includes one or more communication connectors C11 connected to the external devices of the robot 10.

From the viewpoint of maintainability, for example, the drive circuit 50 is accommodated in a separate case from the base case 100 in which the motors 41, 42, 43 and 44 are accommodated. Cables are routed between the case accommodating the drive circuit 50 and the base case 100 to electrically connect the drive circuit 50 and the motors 41, 42, 43 and 44. The cables include, for example, a power cable that supplies driving power from the drive circuit 50 to the motors 41, 42, 43 and 44, and a feedback cable that transmits feedback signals from the rotation angle sensors 71, 72, 73 and 74 to the drive circuit 50. Therefore, in order to mount the robot 10, a sufficient wiring space may be around the chamber 90, in addition to an installation space for the case accommodating the drive circuit 50. Securing these spaces in the substrate processing apparatus is not always easy. Therefore, the robot 10 further includes a circuit case 200. The circuit case 200 accommodates the drive circuit 50 and is attached to the base 11 in a removable manner. For example, the circuit case 200 is attached to the base case 100.

Since the circuit case 200 is attached to the base 11, it is possible to significantly reduce a wiring space required from the drive circuit 50 to the base 11. Therefore, a separate installation space for the circuit case 200 may not be provide, apart from the installation space for the robot 10. Further, when maintenance for the drive circuit 50 is required, the circuit case 200 may be removed for the maintenance of the drive circuit 50 while leaving the base 11 in place. Accordingly, this is effective in achieving both space saving and maintainability.

When it is said that the circuit case 200 is removable from the base case 100, it means that the circuit case 200 is removable from the base case 100 without physically destroying either the base case 100 or the circuit case 200. For example, the circuit case 200 is attached to the base case 100 using fasteners such as bolts, which allow for repeated attachment and removal.

The circuit case 200 may be attached to the base 11 such that the base 11 is positioned between the circuit case 200 and the flange 14. This arrangement helps to suppress the heat transfer to the circuit case 200 from a space where the hands 12 and 13 and the multi-joint arms 20 and 30 are arranged (e.g., the internal space 93 of the chamber 90), thereby suppressing or preventing the drive circuit 50 from overheating. As described above, when the robot 10 is provided with the sealing member 60, the heat transfer from the internal space 93 of the chamber 90 to the internal space of the circuit case 200 may be further reduced, which further suppresses or prevents the overheating of the drive circuit 50.

For example, in a state where the flange 14 is attached to the bottom plate 92, the base 11 is positioned below the flange 14, and the circuit case 200 is positioned below the base 11. The flange 14 may hold the base 11 while keeping the circuit case 200 separated from a floor surface FS. By keeping the circuit case 200 floated from the floor surface FS, further space saving may be achieved.

The base case 100 may include a first frame 110, and the circuit case 200 may include a second frame 210. The first frame 110 imparts a load bearing capacity exceeding the total weight of the hands 12 and 13, multi-joint arms 20 and 30, flange 14, and motors 41, 42, 43 and 44 to the base 11. When it is said that the first frame 110 imparts a load bearing capacity to the base 11, it means that the base 11 does not obtain a required load bearing capacity when the first frame 110 is excluded from the base 11, and that the load bearing capacity of the base 11 is achieved only when the first frame 110 is included in the base 11. The first frame 110 may be responsible for more than half of the load bearing capacity of the base 11, 70% or more of it, or 90% or more of it.

The second frame 210 imparts a load bearing capacity exceeding the total weight of the hands 12 and 13, multi-joint arms 20 and 30, flange 14, motors 41, 42, 43 and 44, and the base 11 to the circuit case 200. When it is said that the second frame 210 imparts a load bearing capacity to the circuit case 200, it means that the circuit case 200 does not obtain a required load bearing capacity when the second frame 210 is excluded from the circuit case 200, and that the load bearing capacity of the circuit case 200 is achieved only when the second frame 210 is included in the circuit case 200. The second frame 210 may be responsible for more than half of the load bearing capacity of the circuit case 200, 70% or more of the load bearing capacity of the circuit case 200, or 90% or more of the load bearing capacity of the circuit case 200.

The second frame 210 may be attached to the first frame 110. When removing the entire robot 10 from the chamber 90 for maintenance, the circuit case 200 and the base 11 may support the hands 12 and 13, multi-joint arms 20 and 30, flange 14, and motors 41, 42, 43 and 44, which further enhances maintainability.

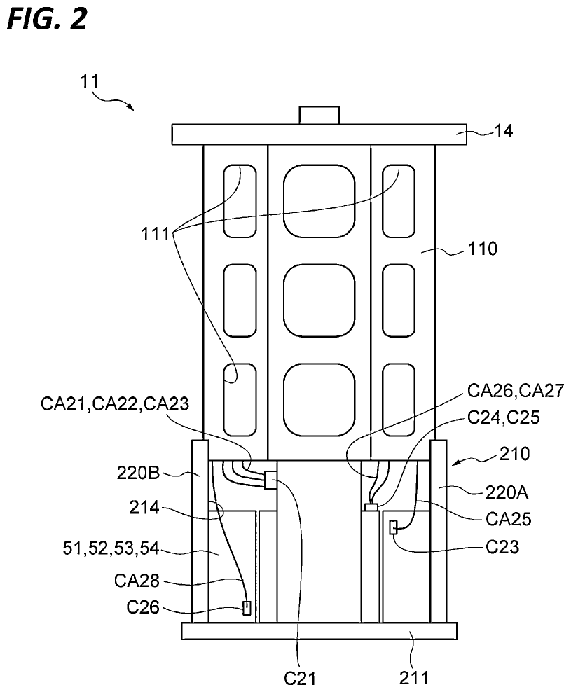

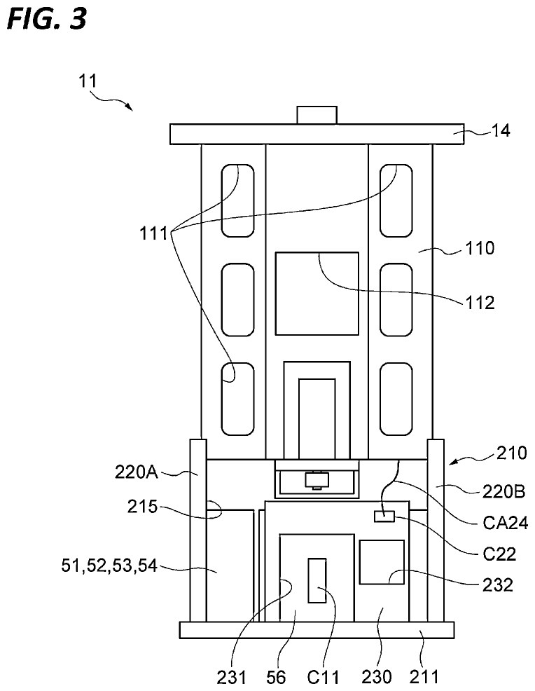

As illustrated in FIGS. 2 and 3, the base case 100 includes the first frame 110 and a cover 120. The first frame 110 is fixed to the underneath of the flange 14, and surrounds at least one of the motors 41, 42, 43 and 44 (e.g., motors 41, 42 and 43) around an axis intersecting the flange 14. For example, the first frame 110 is made of a metallic material such as steel, stainless steel, or aluminum alloy, and has a plurality of openings 111 for weight reduction and other purposes.

The cover 120 surrounds the first frame 110 around an axis intersecting the flange 14, covering at least one (e.g., all) of the plurality of openings 111.

The cover 120 may be divided into a cover 130 and a cover 140 so that each may be removed from the first frame 110 along the radial direction centered on an axis intersecting the flange 14. The cover 130 and the cover 140 each cover the first frame 110 in opposite directions along the radial direction. Each of the covers 130 and 140 is attached to the first frame 110 in a removable manner using fasteners such as bolts. Hereinafter, for convenience of explanation, the direction in which the cover 130 is positioned relative to the first frame 110 will be referred to as “front”, and the direction in which the cover 140 is positioned relative to the first frame 110 will be referred to as “rear”.

The circuit case 200 includes the second frame 210 and a cover 240. The second frame 210 is made of a metallic material such as steel, stainless steel, or aluminum alloy, and has a base plate 211 and a pair of support beams 220A and 220B. The base plate 211 extends to cover the drive circuit 50 from below and supports the drive circuit 50. The pair of support beams 220A and 220B protrude upward from the left and right ends of the drive circuit 50, respectively, to connect the base plate 211 to the first frame 110. Ends (e.g., upper ends) of the pair of support beams 220A and 220B are attached to the first frame 110, respectively. This allows the second frame 210 to support the hands 12 and 13, multi-joint arms 20 and 30, flange 14, base 11, and motors 41, 42, 43 and 44.

The support beams 220A and 220B form an opening 214 to the front and an opening 215 to the rear in the second frame 210. The openings 214 and 215 are used as wiring openings to expose one or more connectors to which the motors 41, 42, 43 and 44 are electrically connected (e.g., to which the aforementioned cables are connected).

The drive circuit 50 includes, for example, power connectors C21 and C22 and feedback connectors C23, C24, C25 and C26. The power connector C21 connects power cables CA21, CA22 and CA23 from the motors 41, 42 and 43 to the servo circuits 51, 52 and 53, respectively. The power connector C22 connects a power cable CA24 from the motor 44 to the servo circuit 54. This allows the power cables CA21, CA22, CA23 and CA24 to supply driving power from the servo circuits 51, 52, 53 and 54 to the motors 41, 42, 43 and 44, respectively.

The feedback connector C23 connects a feedback cable CA25 from the rotation angle sensor 71 to the servo circuit 51. The feedback connector C24 connects a feedback cable CA26 from the rotation angle sensor 72 to the servo circuit 52. The feedback connector C25 connects a feedback cable CA27 from the rotation angle sensor 73 to the servo circuit 53. The feedback connector C26 connects a feedback cable CA28 from the rotation angle sensor 74 to the servo circuit 54. This allows the feedback cables CA25, CA26, CA27 and CA28 to transmit feedback signals from the rotation angle sensors 71, 72, 73 and 74 to the servo circuits 51, 52, 53 and 54, respectively.

As illustrated in FIG. 2, the opening 214 exposes the power connector C21 and the feedback connectors C23, C24, C25 and C26 in a state where the circuit case 200 is attached to the base 11. As illustrated in FIG. 3, the opening 215 exposes the power connector C22 in a state where the circuit case 200 is attached to the base 11. The aforesaid “a state where the circuit case 200 is attached to the base 11” means that at least the second frame 210 is attached to the base 11. The same applies hereinafter. The aforesaid “the opening 214 exposes the power connector C21 and the feedback connectors C23, C24, C25 and C26” means that the opening 214 allows the operator to access the power connector C21 and the feedback connectors C23, C24, C25 and C26 through the opening 214. Similarly, the aforesaid “the opening 215 exposes the power connector C22” means that the opening 215 allows the operator to access the power connector C22 through the opening 215.

The openings 214 and 215 allow the motors 41, 42, 43 and 44 to connect to the drive circuit 50 after attaching the circuit case 200 to the base 11, and allow the motors 41, 42, 43 and 44 to disconnect from the drive circuit 50 after removing the circuit case 200 from the base 11. Therefore, it is possible to further enhance the operational ease of attaching and removing the circuit case 200 with respect to the base 11.

The second frame 210 may further include a sub-frame 230 that protrudes from the base plate 211 to cover the communication circuit 56 from the rear. The sub-frame 230 may have an opening 231 for exposing the communication connector C11.

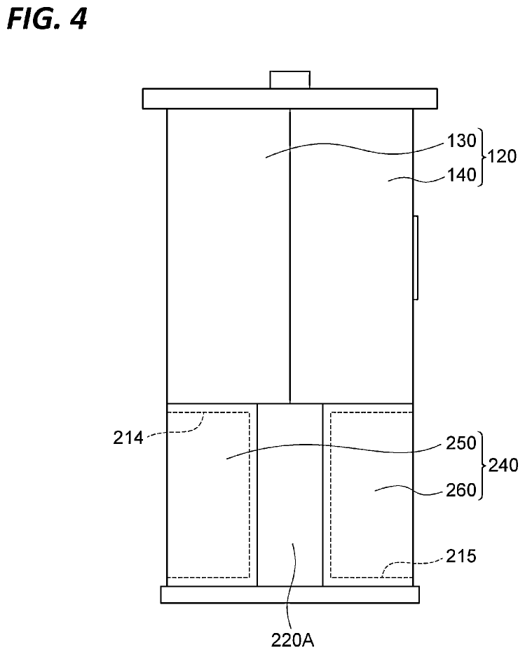

As illustrated in FIG. 4, the cover 240 surrounds the second frame 210 around an axis intersecting the flange 14, covering the openings 214 and 215.

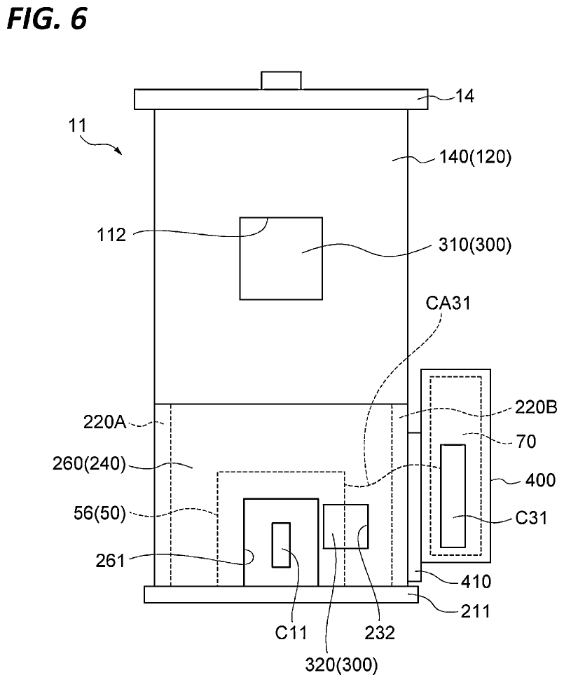

The cover 240 may be divided into a cover 250 and a cover 260 so that each may be removed from the second frame 210 along the radial direction centered on an axis intersecting the flange 14. The cover 250 and the cover 260 each cover the second frame 210 in opposite directions along the radial direction. For example, the cover 250 covers the opening 214 from the front, and the cover 260 covers the opening 215 from the rear. The covers 250 and 260 are attached to the support beams 220A and 220B, respectively, in a removable manner using fasteners such as bolts. The cover 260 may have an opening 261 corresponding to the opening 231. The opening 261 exposes the communication connector C11 (see, e.g., FIG. 6).

In this way, it is possible to attach or remove the cover 250 relative to the second frame 210 in a state where the base 11 is attached to the circuit case 200. Therefore, the cover 250 may open or close the opening 214 in a state where the circuit case 200 is attached to the base 11. Similarly, it is possible to attach or remove the cover 260 relative to the second frame 210 in a state where the base 11 is attached to the circuit case 200. Therefore, the cover 260 may open or close the opening 215 in a state where the circuit case 200 is attached to the base 11. This enhances the operational ease of attaching or removing the circuit case 200 relative to the base 11, while also protecting the interior of the circuit case 200.

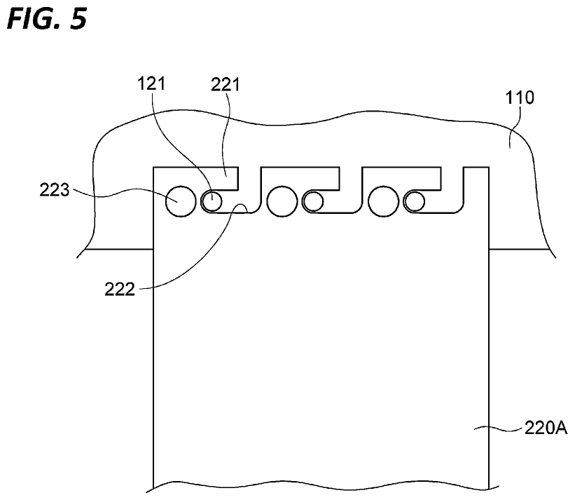

As illustrated in FIG. 5, the ends of the support beams 220A and 220B are attached to the first frame 110 in a removable manner. For example, the robot 10 includes one or more first hooks 121 and one or more second hooks 221. The one or more first hooks 121 are provided on the base 11. The one or more second hooks 221 are provided to be caught by the one or more first hooks 121, respectively, to temporarily fix the circuit case 200 to the base 11. The circuit case 200 is attached to the base 11 with the one or more second hooks 221 caught, respectively, by the one or more first hooks 121.

Since the circuit case 200 is temporarily fixed to the base 11 by the one or more first hooks 121 and the one or more second hooks 221 before attaching the circuit case 200 to the base 11, the operator may attach the circuit case 200 to the base 11 without manually supporting the circuit case 200. Therefore, it is possible to enhance the operational ease of attaching the circuit case 200 to the base 11.

The robot 10 includes a plurality of (e.g., three) first hooks 121 and a plurality of second hooks 221 respectively corresponding to the plurality of first hooks 121, which are provided at the respective ends of the support beams 220A and 220B. Hereinafter, the end of the support beam 220A will be described. Descriptions related to the end of the support beam 220B will be omitted as they overlap with those for the end of the support beam 220A.

For example, the plurality of first hooks 121 are a plurality of pins provided on the outer peripheral surface of a lower end of the first frame 110. The plurality of first hooks 121 are arranged in the circumferential direction of the first frame 110, and protrude outward from the outer peripheral surface of the first frame 110, respectively. The plurality of second hooks 221 are a plurality of hook-shaped portions provided at an upper end of the support beam 220A so as to be caught, respectively, by the plurality of first hooks 121. For example, the upper end of the support beam 220A is formed with a plurality of notches 222, which are arranged in the circumferential direction of the first frame 110 and each receives a respective one of the plurality of first hooks 121.

Each of the plurality of notches 222 is open upward of the support beam 220A, and is bent along the circumferential direction of the first frame 110 at a position away from the upper edge of the support beam 220A. The second hook 221, which is a hook-shaped portion caught by the first hook 121, is formed above a portion of the notch 222 along the circumferential direction of the first frame 110. The support beam 220A is attached to the first frame 110 using a plurality of fasteners 223 at a plurality of locations adjacent respectively to the plurality of notches 222 in the circumferential direction of the first frame 110. The plurality of fasteners 223 are a plurality of bolts.

The bending direction of the plurality of notches 222 in the support beam 220B may be the same as the bending direction of the plurality of notches 222 in the support beam 220A. In this case, in a state where the plurality of first hooks 121 enter, respectively, the plurality of notches 222 of the support beam 220A from above and the plurality of first hooks 121 enter, respectively, the plurality of notches 222 of the support beam 220B from above, rotating the circuit case 200 around an axis intersecting the flange 14 may allow the plurality of second hooks 221 to be caught respectively by the plurality of first hooks 121.

The bending direction of the plurality of notches 222 in the support beam 220B may be opposite to the bending direction of the plurality of notches 222 in the support beam 220A. In this case, in a state where the plurality of first hooks 121 enter each of the plurality of notches 222 of the support beam 220A from above and the plurality of first hooks 121 enter each of the plurality of notches 222 of the support beam 220B from above, sliding the circuit case 200 horizontally may allow the plurality of second hooks 221 to be respectively hooked onto the plurality of first hooks 121.

The plurality of fasteners 223 need at least to be attached to the first frame 110 in a removable manner and be capable of maintaining the support beam 220A attached to the first frame 110, and they are not necessarily limited to the plurality of bolts. For example, the plurality of fasteners 223 may be a plurality of rivets. Further, the plurality of first hooks 121 may also serve as the plurality of fasteners 223, and the plurality of second hooks 221 may also serve as the plurality of fasteners 223. For example, the plurality of first hooks 121 may be a plurality of bolts, which function as the plurality of first hooks 121 when loosely mounted to the first frame 110 but may function as the plurality of fasteners 223 when tightened respectively in a state where the plurality of notches 222 are caught by the plurality of first hooks 121.

As illustrated in FIGS. 3 and 6, the robot 10 may further include a first vent 112, a second vent 232, and a ventilator 300. The first vent 112 is formed in the first frame 110 and the cover 120 to communicate the internal space of the base 11 (e.g., the space surrounded by the first frame 110) with the external space of the base 11 (see, e.g., FIG. 6). The second vent 232 is formed in the second frame 210 and the cover 240 to communicate the internal space of the circuit case 200 with the external space of the circuit case 200 (see, e.g., FIG. 6). The ventilator 300 generates airflow between the first vent 112 and the second vent 232 through the internal space of the base 11 and the internal space of the circuit case 200. The airflow generated by the ventilator 300 in the internal space of the base 11 and the internal space of the circuit case 200 may further suppress or prevent the overheating of the drive circuit 50.

The ventilator 300 may generate airflow from the second vent 232 to the first vent 112 through the internal space of the base 11 and the internal space of the circuit case 200. By making the internal space of the circuit case 200 upstream of ventilation, the overheating of the drive circuit 50 may be further suppressed or prevented. As described above, in a configuration in which all of the motors 41, 42, 43 and 44 are built into the base 11, the internal space of the base 11 may become further overheated. For this configuration, the internal space of the circuit case 200 may be made to be an upstream of ventilation to further suppress or prevent the overheating of the drive circuit 50.

For example, the first vent 112 is formed in the first frame 110 and the cover 140 opens to the rear. The second vent 232 is formed in the sub-frame 230 and the cover 260 opens to the rear. These are examples and may be modified. For example, the first vent 112 may be formed in the first frame 110 and the cover 130 to open to the front. The second vent 232 may be formed in the base plate 211 to open downward.

The ventilator 300 may include a fan 310. The fan 310 is provided at the first vent 112 to direct a gas from the internal space of the base 11 to the external space of the base 11. For example, the fan 310 includes a rotating blade that generates airflow from the internal space of the base 11 to the external space of the base 11 by rotation, and is attached to the first frame 110 so that the rotating blade covers at least a part of the first vent 112. By placing the fan 310 at the most downstream point in the internal spaces of the base 11 and the circuit case 200, gas accumulation in the internal space of the base 11 may be reduced, and heat transfer from the internal space of the base 11 to the internal space of the circuit case 200 may be further reduced.

The ventilator 300 may include a second fan 320 instead of the fan 310. The second fan 320 is provided at the second vent 232 to direct a gas from the external space of the circuit case 200 to the internal space of the circuit case 200. For example, the second fan 320 includes a rotating blade that generates airflow from the external space of the circuit case 200 to the internal space of the circuit case 200 by rotation, and is attached to the sub-frame 230 so that the rotating blade covers at least a part of the second vent 232. By placing the second fan 320 at the most upstream point in the internal spaces of the base 11 and the circuit case 200, gas accumulation in the internal space of the circuit case 200 may be reduced, and heat transfer from the internal space of the base 11 to the internal space of the circuit case 200 may be further reduced.

The ventilator 300 may include both the fan 310 and the second fan 320. This may help to reduce gas accumulation in both the internal spaces of the base 11 and the circuit case 200 and to further suppress or prevent heat transfer from the internal space of the base 11 to the internal space of the circuit case 200.

In this way, in a configuration in which the internal space of the circuit case 200 is upstream of ventilation, a part of the drive circuit 50 (e.g., the calculation circuit 55) may protrude from the circuit case 200 toward the flange 14 and may be accommodated in the base 11 (see, e.g., FIG. 1). One of the motors 41, 42, 43 and 44 or the transmission mechanism 46 may protrude from the first frame 110 in the direction away from the flange 14 (e.g., downward) and may be accommodated in the circuit case 200.

By utilizing the excess space within the base 11 for accommodating the drive circuit 50, the circuit case 200 may be made more compact, achieving further space saving. Further, utilizing the excess space within the circuit case 200 for accommodating the transmission mechanism 46 and others may help to make the base 11 more compact, achieving further space saving. Since the internal space of the circuit case 200 is upstream of ventilation, the overheating of the drive circuit 50 may be suppressed or prevented both when accommodating a part of the drive circuit 50 in the base and when accommodating the transmission mechanism 46 and others in the circuit case 200.

As illustrated in FIG. 6, the robot 10 may further include a power supply circuit 70 and a power supply case 400. The power supply circuit 70 supplies power to the drive circuit 50. For example, the power supply circuit 70 generates a plurality of power supply powers with different voltages and supplies them to the drive circuit 50. The power supply case 400 accommodates the power supply circuit 70 and is attached to the circuit case 200 in a removable manner.

Since the power supply case 400 is attached to the circuit case 200, a wiring space from the power supply circuit 70 to the drive circuit 50 may be significantly reduced. There is no need to provide a separate installation space for the power supply case 400 apart from the installation space for the robot 10. Further, when maintenance for the power supply circuit 70 is required, the power supply case 400 may be removed for the maintenance of the power supply circuit 70 without having to remove the hands 12 and 13, multi-joint arms 20 and 30, base 11, and circuit case 200. This is further effective in achieving both space saving and maintainability.

The power supply case 400 may be attached to the circuit case 200 in such a way that it is aligned with the circuit case 200 in a direction (e.g., the horizontal direction) intersecting the direction in which the base 11 and the circuit case 200 are arranged (e.g., the vertical direction). This allows the surrounding space of the circuit case 200 to be utilized for the arrangement of the power supply case 400. In the illustrated example, the power supply case 400 is attached to the support beam 220B using removable fasteners as bolts.

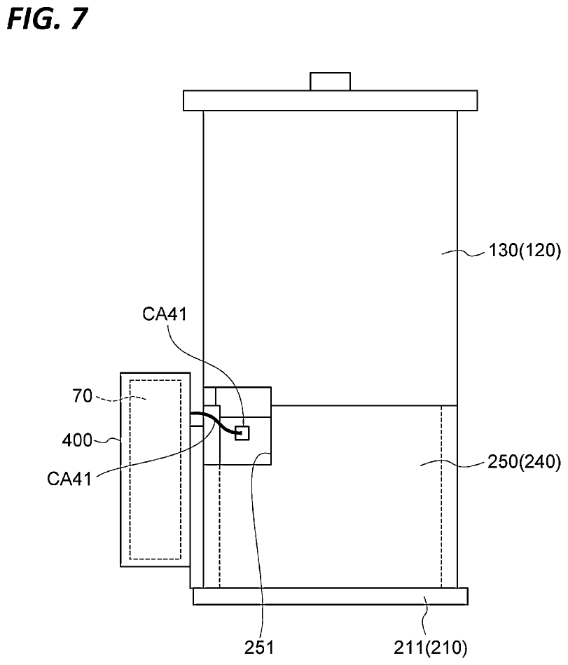

The power supply case 400 may be attached to the support beam 220B via a bracket 410. For example, the power supply case 400 may be fixed to the plate-shaped bracket 410 interposed between the power supply case 400 and the support beam 220B, and the bracket 410 may be attached to the support beam 220B using the aforementioned fasteners. As illustrated in FIG. 7, the robot 10 may further have an opening 251 that allows wiring from the power supply circuit 70 to the drive circuit 50 even in a state where the cover 240 is attached to the second frame 210 and the cover 120 is attached to the first frame 110. In the example of FIG. 7, the opening 251 is formed at the lower right end of the cover 130 and the upper right end of the cover 250.

For example, the drive circuit 50 further includes one or more power supply connectors C41. The one or more power supply connectors C41 connect one or more power supply cables CA41 from the power supply case 400 to the servo circuits 51, 52, 53 and 54, calculation circuit 55, and communication circuit 56, respectively. This allows the one or more power supply cables CA41 to supply the plurality of power supply powers generated by the power supply circuit 70 to the servo circuits 51, 52, 53 and 54, calculation circuit 55, and communication circuit 56.

The opening 251 exposes the one or more power supply connectors C41 in a state where the cover 130 is attached to the first frame 110 and the cover 250 is attached to the second frame 210. The aforementioned “the opening 251 exposes the one or more power supply connectors C41” means that the opening 251 allows the operator to access the one or more power supply connectors C41 through the opening 251. For example, the one or more power supply cables CA41 are pulled out from the outer surface of the power supply case 400 facing the circuit case 200, and are respectively connected to the one or more power supply connectors C41 through the openings 251.

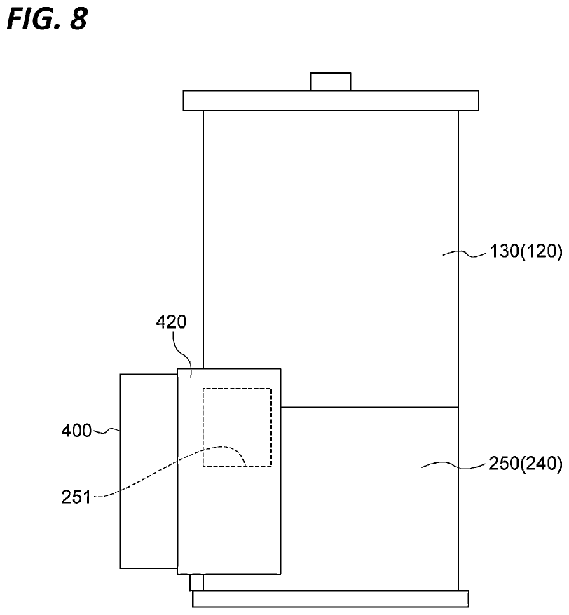

As illustrated in FIG. 8, the robot 10 may further include a cover 420 to cover the opening 251. For example, the cover 420 is attached to the power supply case 400 in a removable manner using fasteners such as bolts.

Returning to FIG. 6, the robot 10 may further include a communication connector C31 provided in the power supply case 400 and a communication cable CA31 that electrically connects the communication connector C31 to the drive circuit 50. The drive circuit 50 may be configured to communicate with external devices through the communication connector C31 and the communication cable CA31. Being provided in the power supply case 400 includes being provided within the power supply case 400. By utilizing the excess space in the power supply case 400 for the arrangement of the communication connector C31, the space may be further saved.

For example, the communication circuit 56 may be configured to communicate with external devices through the communication connector C31 and the communication cable CA31. As described above, examples of external devices may include a higher-level controller and a calibration device. The communication circuit 56 may be configured to communicate with the higher-level controller through the communication connector C11 and to communicate with the calibration device through the communication connector C31. By differentiating the connection destinations of the communication connector C11 and the communication connector C31, the operational ease of wiring may be further enhanced.

### SUMMARY

The embodiments illustrated above include the following configurations.

Configuration (1): a robot 10 comprising a hand 12 configured to support a substrate W, a base 11, a multi-joint arm 20 configured to connect the hand 12 to the base 11, one or more motors 4 configured to drive the multi-joint arm 20 and change a position of the hand 12 relative to the base 11, a drive circuit 50 configured to supply driving power to the one or more motors 40, and a circuit case 200 configured to accommodate the drive circuit 50 and attached to the base 11 in a removable manner.

Since the circuit case 200 is attached to the base 11, the wiring space may be significantly reduced. It is also no longer necessary to provide a separate installation space for the circuit case 200 apart from the installation space for the robot 10. Further, when maintenance for the drive circuit 50 is required, the circuit case 200 may be removed for the maintenance of the drive circuit 50 while leaving the multi-joint arm 20 in place. This is effective in achieving both space saving and maintainability.

Configuration (2): the robot according to configuration (1), further comprising a flange 14 extending to partition between the arm and the base 11, wherein the circuit case 200 is attached to the base 11 such that the base 11 is positioned between the circuit case 200 and the flange 14.

The base 11 reduces heat transfer to the circuit case 200 from a space where the hand 12 and the arm are arranged, suppressing or preventing the drive circuit 50 from overheating.

Configuration (3): the robot 10 according to configuration (2), further comprising a first vent 112 that communicates an internal space of the base 11 with an external space of the base 11, a second vent 232 that communicates an internal space of the circuit case 200 with an external space of the circuit case 200, and a ventilator 300 that generates airflow between the first vent 112 and the second vent 232 through the internal space of the base 11 and the internal space of the circuit case 200.

This may further suppress or prevent the overheating of the drive circuit 50.

Configuration (4): the robot 10 according to configuration (3), wherein the ventilator 300 generates airflow from the second vent 232 to the first vent 112 through the internal space of the base 11 and the internal space of the circuit case 200.

By making the internal space of the circuit case 200 upstream of ventilation, the overheating of the drive circuit 50 may be further suppressed or prevented.

Configuration (5): the robot 10 according to configuration (4), wherein the ventilator 300 includes a fan 310 provided at the first vent 112 to direct a gas from the internal space of the base 11 to the external space of the base 11.

This may further suppress or prevent heat transfer from the internal space of the base 11 to the internal space of the circuit case 200.

Configuration (6): the robot 10 according to configuration (5), wherein the ventilator 300 further includes a second fan 320 provided at the second vent 232 to direct a gas from the external space of the circuit case 200 to the internal space of the circuit case 200.

This may further suppress or prevent heat transfer from the internal space of the base 11 to the internal space of the circuit case 200.

Configuration (7): the robot 10 according to any one of configurations (4) to (6), wherein the one or more motors 40 are built into the base 11.

While this may increase the temperature inside the base 11, the internal space of the circuit case 200 being upstream of ventilation may further suppress or prevent the overheating of the drive circuit 50.

Configuration (8): the robot 10 according to any one of configurations (4) to (7), wherein a part of the drive circuit 50 protrudes from the circuit case 200 toward the flange 14 and is accommodated in the base 11.

By utilizing the excess space within the base 11 for accommodating the drive circuit 50, the circuit case 200 may be made more compact, achieving further space saving. Since the internal space of the circuit case 200 is upstream of ventilation, the overheating of the drive circuit 50 is suppressed or prevented even when a part of the drive circuit 50 is accommodated in the base 11.

Configuration (9): the robot 10 according to any one of configurations (2) to (8), further comprising a sealing member 60 provided on the flange 14 to airtightly separate the internal space of the base 11 from the external space of the base 11.

This may further suppress or prevent heat transfer from the space where the hand 12 and the arm are arranged to the internal space of the circuit case 200, suppressing or preventing the overheating of the drive circuit 50.

Configuration (10): the robot 10 according to any one of configurations (2) to (9), wherein the base 11 and the circuit case 200 are located below the flange 14, and the flange 14 holds the base 11 with the circuit case 200 separated from a floor surface.

This allows further space saving by keeping the circuit case 200 floated from the floor.

Configuration (11): the robot 10 according to configuration (10), wherein the base 11 includes a first frame 110 that imparts a load bearing capacity exceeding a total weight of the hand 12, the multi-joint arm 20, the flange 14, and the one or more motors 40 to the base 11, wherein the circuit case 200 includes a second frame 210 that imparts a load bearing capacity exceeding a total weight of the hand 12, the multi-joint arm 20, the flange 14, the one or more motors 40, and the base 11 to the circuit base 200, and wherein the second frame 210 is attached to the first frame 110.

This further enhances maintainability by supporting the hand 12, multi-joint arm 20, flange 14, and one or more motors 40 with the circuit case 200 and the base 11 during maintenance.

Configuration (12): the robot 10 according to configuration (10) or (11), further comprising a first hook 121 provided on the base 11 and a second hook 221 provided on the circuit case 200 to be caught by the first hook 121 to temporarily fix the circuit case 200 to the base 11, wherein the circuit case 200 is attached to the base 11 in a state where the second hook 221 is caught by the first hook 121.

This may enhance the operational ease of attaching the circuit case 200 to the base 11.

Configuration (13): the robot 10 according to any one of configurations (1) to (12), wherein the drive circuit 50 includes a connector to which the one or more motors 40 are electrically connected, and wherein the circuit case 200 has wiring openings 214 and 215 that expose the connector in a state where the circuit case 200 is attached to the base 11.

The one or more motors 40 may be connected to the drive circuit 50 after attaching the circuit case 200 to the base 11, and the circuit case 200 may be removed from the base 11 after separating the one or more motors 40 from the drive circuit 50. Therefore, it is possible to further enhance the operational ease of attaching or removing the circuit case 200 relative to the base 11.

Configuration (14): the robot 10 according to configuration (13), further comprising a cover capable of opening or closing the wiring openings 214 and 215 while the circuit case 200 is attached to the base 11.

This may further enhance the operational ease of attaching or removing the circuit case 200 relative to the base 11, while also protecting the interior of the circuit case 200.

Configuration (15): the robot 10 according to any one of configurations (1) to (14), further comprising a power supply circuit 70 configured to supply power to the drive circuit 50, and a power supply case 400 configured to accommodate the power supply circuit 70 and attached to the circuit case 200 in a removable manner.

Since the power supply case 400 is attached to the circuit case 200, a wiring space from the power supply circuit 70 to the drive circuit 50 may be significantly reduced. There is no need to provide a separate installation space for the power supply case 400 apart from the installation space for the robot 10. Further, when maintenance for the power supply circuit 70 is required, the power supply case 400 may be removed for the maintenance of the power supply circuit 70 without having to remove the multi-joint arm 20 and the circuit case 200. This is further effective in achieving both space saving and maintainability.

Configuration (16): the robot 10 according to configuration (15), wherein the power supply case 400 is attached to the circuit case 200 such that it is aligned with the circuit case 200 in a direction intersecting a direction in which the base 11 and the circuit case 200 are arranged.

This allows the surrounding space of the circuit case 200 to be utilized for the arrangement of the power supply case 400.

Configuration (17): the robot 10 according to configuration (15), further comprising a communication connector C31 provided in the power supply case 400 and a communication cable CA31 configured to electrically connect the communication connector C31 to the drive circuit 50, wherein the drive circuit 50 communicates with an external device through the communication cable CA31 and the communication connector C31.

By utilizing the excess space in the power supply case 400 for the arrangement of the communication connector C31, the space may be further saved.

Configuration (18): a substrate transfer device 1 comprising the robot 10 according to any one of configurations (2) to (6), and a chamber 90 configured to accommodate the hand 12 and the multi-joint arm 20, wherein the chamber 90 has a chamber opening 94 to position the base 11 and the circuit case 200 outside the chamber 90, and wherein the flange 14 is attached to the chamber 90 to close the chamber opening 94.

Configuration (19): the substrate transfer device 1 according to configuration (18), wherein the chamber opening 94 opens downward, and the flange 14 holds the base 11 with the circuit case 200 separated from the floor surface.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A robot comprising:
a hand configured to support a substrate;
a base;
a multi-joint arm configured to connect the hand to the base;
one or more motors configured to drive the multi-joint arm and change a position of the hand relative to the base;
a drive circuit configured to supply driving power to the one or more motors; and
a circuit case configured to accommodate the drive circuit and be attached to the base in a removable manner.

2. The robot according to claim 1, further comprising:
a flange extending to partition between the arm and the base,
wherein the circuit case is attached to the base such that the base is positioned between the circuit case and the flange.

3. The robot according to claim 2, further comprising:
a first vent configured to communicate an internal space of the base with an external space of the base;
a second vent configured to communicate an internal space of the circuit case with an external space of the circuit case; and
a ventilator configured to generate airflow between the first vent and the second vent through the internal space of the base and the internal space of the circuit case.

4. The robot according to claim 3, wherein the ventilator generates airflow from the second vent to the first vent through the internal space of the base and the internal space of the circuit case.

5. The robot according to claim 4, wherein the ventilator includes a fan provided at the first vent to direct a gas from the internal space of the base to the external space of the base.

6. The robot according to claim 5, wherein the ventilator further includes a second fan provided at the second vent to direct a gas from the external space of the circuit case to the internal space of the circuit case.

7. The robot according to claim 4, wherein the one or more motors are built into the base.

8. The robot according to claim 4, wherein a part of the drive circuit protrudes from the circuit case toward the flange and is accommodated in the base.

9. The robot according to claim 3, further comprising
a sealing member provided on the flange to airtightly separate the internal space of the base from the external space of the base.

10. The robot according to claim 2, wherein
the base and the circuit case are located below the flange, and
the flange holds the base with the circuit case separated from a floor surface.

11. The robot according to claim 10, wherein
the base includes a first frame that imparts a load bearing capacity exceeding a total weight of the hand, the multi-joint arm, the flange, and the one or more motors to the base,
the circuit case includes a second frame that imparts a load bearing capacity exceeding a total weight of the hand, the multi-joint arm, the flange, the one or more motors, and the base to the circuit base, and
the second frame is attached to the first frame.

12. The robot according to claim 10, further comprising
a first hook provided on the base; and
a second hook provided on the circuit case to be caught by the first hook to temporarily fix the circuit case to the base,
wherein the circuit case is attached to the base in a state where the second hook is caught by the first hook.

13. The robot according to claim 1, wherein
the drive circuit includes a connector to which the one or more motors are electrically connected, and
the circuit case has wiring openings that expose the connector in a state where the circuit case is attached to the base.

14. The robot according to claim 13, further comprising
a cover capable of opening or closing the wiring openings while the circuit case is attached to the base.

15. The robot according to claim 1, further comprising
a power supply circuit configured to supply power to the drive circuit, and
a power supply case configured to accommodate the power supply circuit and attached to the circuit case in a removable manner.

16. The robot according to claim 15, wherein the power supply case is attached to the circuit case such that it is aligned with the circuit case in a direction intersecting a direction in which the base and the circuit case are arranged.

17. The robot according to claim 15, further comprising
a communication connector provided in the power supply case; and
a communication cable configured to electrically connect the communication connector to the drive circuit,
wherein the drive circuit communicates with an external device through the communication cable and the communication connector.

18. A substrate transfer device comprising:
the robot according to claim 2; and
a chamber configured to accommodate the hand and the multi-joint arm,
wherein the chamber has a chamber opening to position the base and the circuit case outside the chamber, and
the flange is attached to the chamber to close the chamber opening.

19. The substrate transfer device according to claim 18, wherein
the chamber opening opens downward, and
the flange holds the base with the circuit case separated from a floor surface.
